(19) United States
(12) Patent Application Publication
(10) Pub. No.: US 2007/0181905 A1
(43) Pub. Date: Aug. 9, 2007

(54) Light emitting diode having enhanced side emitting capability

(76) Inventors: Hui-Heng Wang, Taoyuan City (TW); Jin-Hsiang Liu, Taipei City (TW); Kun-Chuan Lin, Taipei City (TW)

Correspondence Address: LIN & ASSOCIATES INTELLECTUAL PROPERTY, P.O. BOX 2339, SARATOGA, CA, 95070-0339, US

(21) Appl. No.: 11/348,650

(22) Filed: Feb. 7, 2006

(51) Int. Cl. H01L 33/00

(52) U.S. Cl. 257/103

(57) ABSTRACT

A LED structure with enhanced side-emitting capability is provided. An embodiment of The LED structure comprises, on top of a substrate, a metallic layer, a non-alloy ohmic contact layer, a thick transparent layer, a light generating structure, sequentially arranged in the this order from bottom to top. The metallic layer functions a reflective mirror and is made of a pure metal or a metal nitride for superior reflectivity. The non-alloy ohmic contact layer is interposed between the light generating structure and the metallic layer so as to achieve the required low resistance electrical conduction. The thick transparent layer extracts a significant portion of the light to the sides of the LED structure. The thick transparent layer, made of a semiconductor material or a dielectric material having an refractive index between 1.5 to 3.5, could be located either above, below or both above and below the light generating structure.

### BACKGROUND OF THE INVENTION

1. Field of the Invention

The present invention generally relates to light emitting diodes (LEDs), and more particularly to a light emitting diode having a transparent layer to enhance its side emitting capability.

2. The Prior Arts

The continuous improvement to the brightness of LEDs is a relentless quest of the relevant industries and many techniques have been disclosed in recent years. Conventionally, a LED structure has a lateral dimension about 200˜350 μm and, for a high-powered LED, it is abut 350˜1,000 μm, while the thickness of the light generating structure of the LED structure is only about 1 μm. It is therefore quite nature that most, if not all, of the brightness enhancement techniques mainly focus on increasing the power of the light emitted from the top of the LED structure.

FIG. 1a is a schematic sectional view showing a conventional packaging structure of a LED chip. As illustrated, a LED chip 16 is placed on a substrate 19 and electrically connected to the electrodes 15 on the substrate 19 via bonding wires 13. The LED chip 16 is surrounded by a reflection plate 14 having slant reflective surface which directs the light emitted from the LED upward. Please note that the thickness of the LED chip 16 is exaggerated. However, this is to manifest that, if the LED chip 16 could have an increased amount of light emitted from the side of its structure, the brightness of the LED package would be enhanced significantly as well.

Besides increasing the brightness of the LEDs, some recent applications of the LEDs also suggest a requirement for the LED chips to have more light emitted from the sides, instead of from the top of the LED chips. In recent years, LED-based, direct-lit backlight modules have become the mainstream light source for large-size liquid crystal display (LCD) devices, replacing the conventional edge-lit technologies using, for example, cold cathode fluorescent lamps (CCFLs). Most of these LED-based, direct-lit backlight modules employ a light mixing plate in front of an array of red-, green-, and blue-light LEDs to produce uniform planar white light for the LCD devices as various colored lights propagate along the light mixing plate and undergo multiple internal reflections.

To enhance the light uniformity and color mixing, a number of approaches have been proposed, for example, as those shown in FIGS. 1b and 1c. In FIG. 1b a light blocker 10 is positioned right in front of a LED chip 20 to allow only the light emitted from the sides of the LED chip 20 to enter the light mixing plate 30 so that the light could traverse a longer distance to achieve better color mixing. Based on the same principle, in FIG. 1c, the LED chip 20 is equipped with a side emitting lens 40 in the shape of an inverted cone to direct the light substantially 90 degrees off the optical axis of LED chip 20 into a 360-degree rotationally symmetrical pattern.

The foregoing approaches adopt chip-level solutions to enhance the side-emitting capability of LEDs. In contrast, U.S. Pat. No. 5,233,204 discloses an epitaxial solution to increase the amount of light emitted from the sides of a LED while reducing the amount of light absorbed by the substrate. According to U.S. Pat. No. 5,233,204, the LED structure contains a light absorbing substrate 101, a light generating structure 102, and a thick transparent layer 103, sequentially stacked in this order from bottom to top as shown in FIG. 1d. The thick transparent layer 103 is usually made of a material having a bandgap larger than the light energy emitted from the light generating structure 102 so that the transparent layer 103 will not absorb the light produced by the light generating structure 102. In addition and most importantly, the thickness of the transparent layer 103 is a function of the width of the LED structure and the critical angle at which light is internally reflected within the transparent layer 103. As such, the LED structure constructed could double the light output efficiency than a prior art LED due to the increased amount of light emitted from the sides. U.S. Pat. No. 5,233,204 also suggests that the thick transparent layer 103 could be located either above, below or both above and below the light generating structure 102.

On the other hand, U.S. Pat. No. 5,376,580 discloses a LED structure which increases the overall brightness of the LED while obviating the problem of light absorbing substrate. The LED structure contains a light generating structure 112 initially grown on a temporary substrate (not shown). The LED structure is then wafer-bonded to a reflective mirror 114 (on top of a permanent substrate 111) and has the temporary substrate subsequently removed, whose result is depicted in FIG. 1e. The problem with the approach is that the reflective mirror 114's reflective surface is directly involved in the wafer-bonding process, which would lead to roughness of the reflective surface, or reactions and contaminations to the reflective surface.

U.S. patent application Ser. No. 11/180,013 and U.S. patent application Ser. No. 11/180,002, both filed by the present inventor on Jul. 12, 2005, suggest a significantly improved solution. The disclosed LED structure contains, on a side of a substrate, a metallic layer, a non-alloy ohmic contact layer, and a light generating structure, sequentially arranged in this order from bottom to top. The metallic layer functions as a reflective mirror and the non-alloy ohmic contact layer is interposed between the light generating structure and the metallic layer so as to achieve the required low resistance electrical conduction. The metallic layer is grown on the non-alloy ohmic contact layer prior to wafer-bonding the substrate. The metallic layer's reflective surface therefore is not involved in the wafer-bonding process. As such, roughness of the reflective surface or reactions and contaminations to the metallic layer's reflective surface can be avoided. The metallic layer thereby offers a much superior reflectivity than the reflective mirrors developed by prior arts.

### SUMMARY OF THE INVENTION

In light of the aforementioned techniques, the present invention combines the thick transparent layer and the reflective mirror to significantly improve the side-emitting capability of a LED at the epitaxial level.

The LED structure according to an embodiment of the present invention comprises, on top of a substrate, a metallic layer, a non-alloy ohmic contact layer, a thick transparent layer, a light generating structure, sequentially arranged in the this order from bottom to top. The metallic layer functions a reflective mirror and is made of a pure metal or a metal nitride for superior reflectivity. The non-alloy ohmic contact layer is interposed between the light generating structure and the metallic layer so as to achieve the required low resistance electrical conduction.

The metallic layer reflects the light produced by the light generating structure to the top of the LED structure where a significant portion of the light is extracted to the sides of the LED structure by the thick transparent layer. The thick transparent layer is made of a semiconductor material or a dielectric material having a refractive index between 1.5 to 3.5 and a bandgap larger than the light energy emitted from the light generating structure. The thick transparent layer could be located either above, below or both above and below the light generating structure. The thickness of each thick transparent layer should satisfy at least one of the following three criteria: (1) the thickness is at least 1 μm; (2) the thick transparent layer is at least as thick as the light generating structure of the LED structure; and (3) the thickness is at least 0.005 times the lateral dimension of the LED structure.

The material used for the non-alloy ohmic contact layer could be optically transparent or absorbing. For absorbing non-alloy ohmic contact layer, a number of recesses could be optionally formed along the bottom surface so as to reduce light absorption and to improve injection current distribution. For transparent non-alloy ohmic contact layer, recesses could still be formed for improving injection current distribution.

To further prevent the metallic layer from intermixing with the non-alloy ohmic contact layer and the light generating structure, and to maintain the flatness of the reflective surface of the metallic layer, an optical transparent and electrically conductive dielectric layer could be interposed between the metallic layer and the non-alloy ohmic contact layer.

The substrate could be either electrically conductive or non-electrically conductive. If non-electrically conductive substrate is used, in packaging the LED structure into a chip, the electrodes for the LED chip have to be arranged in a planar fashion. If electrically conductive substrate is used, the electrodes could be arranged in a vertical or planar fashion. For planar electrode arrangement, the LED structure could have an optional insulating layer positioned between the substrate and the bottommost metallic layer for a superior insulating property.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1a is a schematic sectional view showing a conventional packaging structure of a LED chip.

FIG. 1b is a schematic view showing the configuration of a LED chip in front of a color mixing plate in a conventional direct-lit backlight module.

FIG. 1c is a schematic view showing the configuration of a LED chip in front of a color mixing plate in another conventional direct-lit backlight module.

FIG. 1d is a schematic sectional view showing a conventional LED structure employing a thick transparent layer to enhance its side emitting capability.

FIG. 1e is a schematic sectional view showing a conventional LED structure employing a reflective mirror to avoid light absorption by the substrate.

FIG. 2a is a schematic sectional view showing a LED structure according to a first embodiment of the present invention.

FIG. 2b is a schematic sectional view showing a LED structure according to a second embodiment of the present invention.

FIG. 2c is a schematic sectional view showing a LED structure according to a third embodiment of the present invention.

FIG. 3a is a schematic sectional view showing a LED structure according to a fourth embodiment of the present invention.

FIG. 3b is a schematic sectional view showing a LED structure according to a fifth embodiment of the present invention.

FIGS. 4a˜4c are schematic sectional views showing the process of forming the LED structure of FIG. 2c.

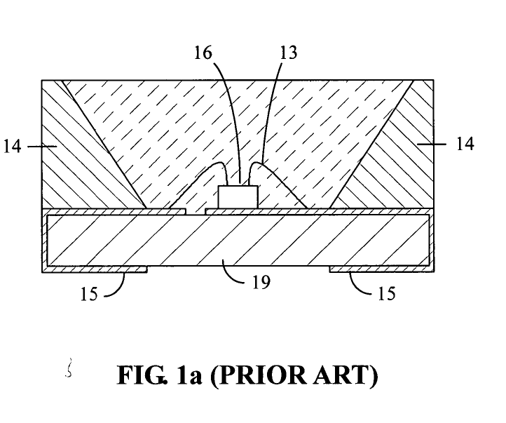

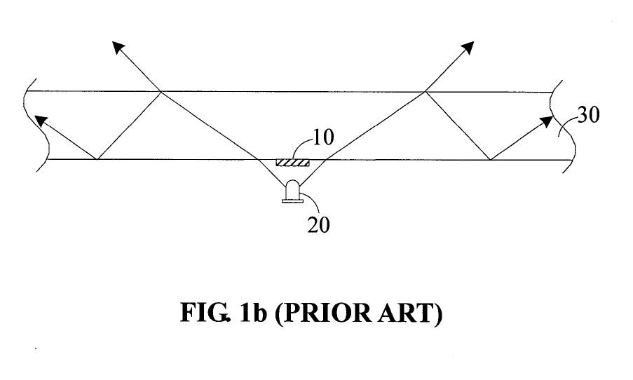

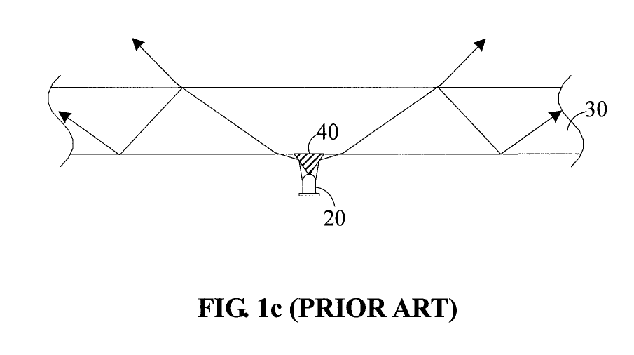

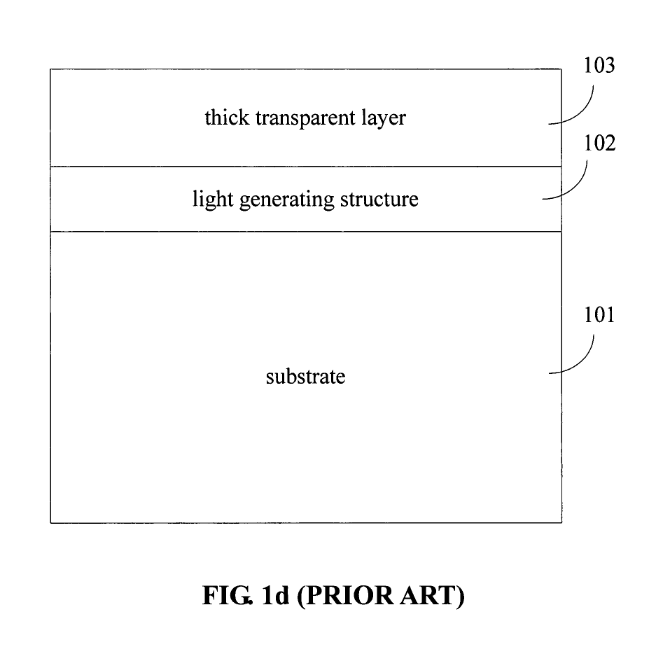

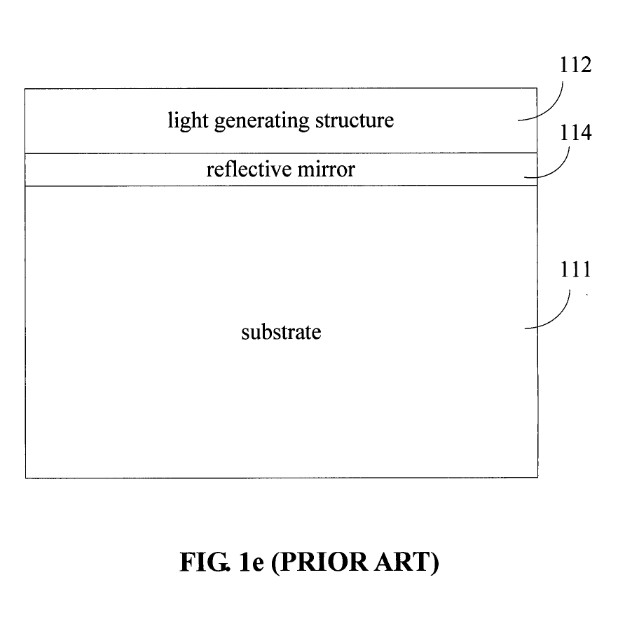

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

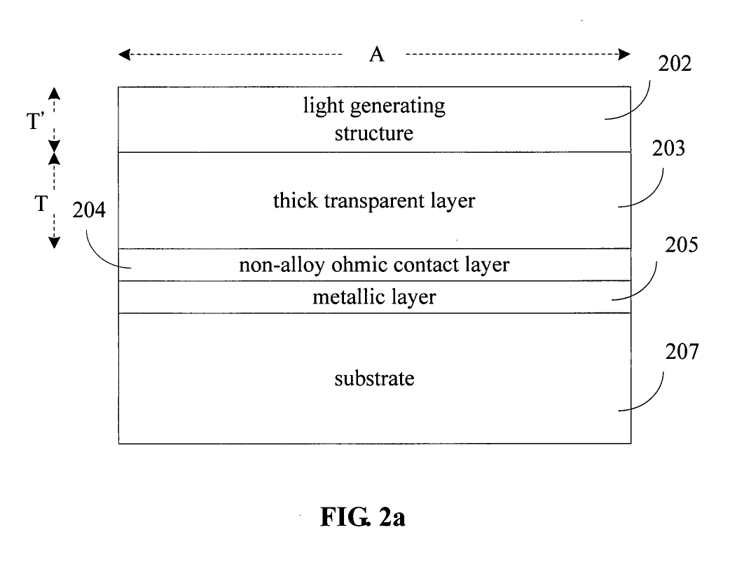

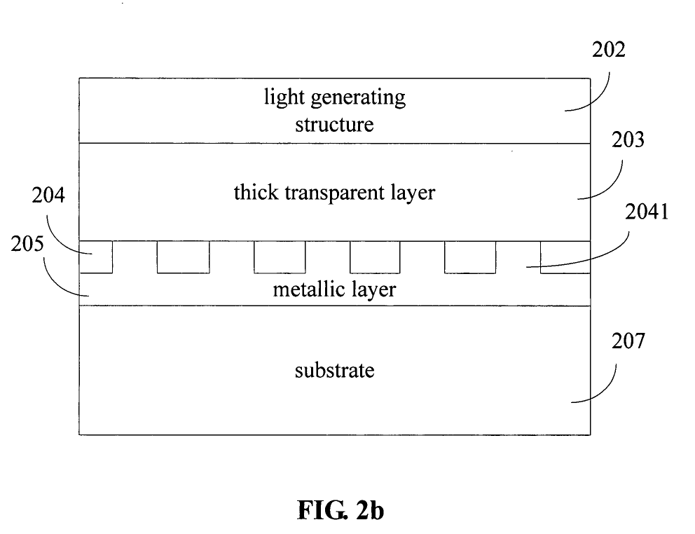

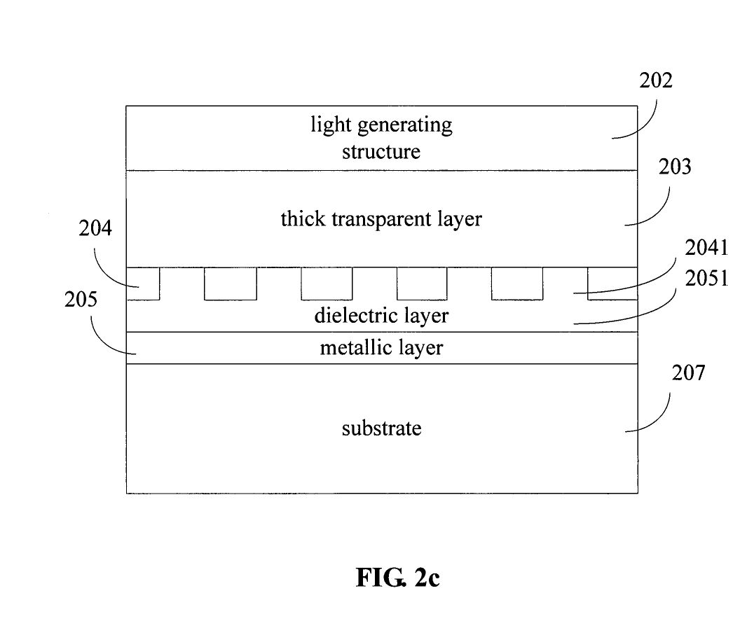

FIG. 2a is a schematic sectional view showing the LED structure according to a first embodiment of the present invention. As illustrated, the LED structure contains a light generating structure 202, which includes active p-n junction layers made of, for example, group III-V compound semiconductor for generating lights in response to the conduction of current. The exact detail of the light generating structure 202 is not the subject matter of the present invention and is therefore omitted here for simplicity. In the following, for ease of reference, all directions towards or locations closer to the light generating structure 202 are referred to as the top direction or upper location, and the opposite as the bottom direction or lower location.

The light generating structure 202 is on top of a thick transparent layer 203, which is designed to function as a “window” to extract light from the sides of the LED structure. The U.S. Pat. No. 5,233,204 has taught that the thick transparent layer should have an appropriate thickness determined by the lateral dimension of the LED structure and the critical angle at which light is internally reflected within the thick transparent layer, to ensure an increased amount of light is emitted from the sides of the LED structure and light absorbed by the substrate is minimized. The critical angle is determined by the refractive indices of the thick transparent layer and the medium where the LED structure is placed. The U.S. Pat. No. 5,233,204 therefore suggests that the thick transparent layer can be made of GaP, GaAsP, and AlGaAs, whose refractive indices are around 3.0˜3.5, as the entire LED structure will be embedded in epoxy in a subsequent packaging process whose refractive index is 1.5.

As will be described later, the present invention needn't worry about the light absorption by the substrate with the configuration of a metallic layer on top of the substrate as a reflective mirror. With numerous experiments, the present invention discovers that the thick transparent layer 203 can be made of not only a semiconductor material but also a dielectric material, with a wider refractive index range from 1.5 to 3.5. Some typical examples of the materials used for the thick transparent layer 203 include, but are not limited to, AlP, AlN, AlAs, AlGaP, and Alₗ₋ₓGaₓIn_{y}P (x≦0.5, 0<y≦1), in addition to the GaP, GaAsP, and AlGaAs suggested by the U.S. Pat. No. 5,233,204. The material Alₗ₋ₓGaₓIn_{y}P requires some elaboration. Depending on its composition, Alₗ₋ₓGaₓIn_{y}P is more of a light generating material if having a smaller amount of aluminum, or more of a transparent material if having a larger amount of aluminum. For example, Alₗ₋ₓGaₓIn_{y}P would be transparent to light with wavelength above 555 nm if (x) is less than 0.53, and Alₗ₋ₓGaₓIn_{y}P would be transparent to visible light with specified wavelength according to the composition (x). Therefore, the (x) composition of Alₗ₋ₓGaₓIn_{y}P for the thick transparent layer 203 could be adjusted based on the color of the light produced by the light generating structure 202. On the other hand, the lattice constant of the thick transparent layer 203 is mostly determined by the amount of indium in Alₗ₋ₓGaₓIn_{y}P. Therefore, the (y) composition of Alₗ₋ₓGaₓIn_{y}P for the thick transparent layer 203 could be adjusted so as to achieve a better epitaxial quality. It should be well-known to people skilled in the related art that, no matter what material is used for the thick transparent layer, it should have a bandgap larger than the light energy emitted from the light generating structure 202 so that the thick transparent layer 203 will not absorb the light radiated from the light generating structure 202.

If the thick transparent layer 203 is too thick, in addition to the lengthened growing time, the light output efficiency would be decreased as well from the increased electrical resistance and light absorption within the thick transparent layer 203. On the other hand, if it is too thin, the light would suffer severe internal reflection within the thick transparent layer 203. Therefore, once the material and the critical angle of the thick transparent layer 203 are determined, an appropriate thickness of the thick transparent layer 203 can be decided, based on the dimension of the LED structure. A LED structure usually has a lateral dimension (A) about 200˜350 μm and, for a high-powered LED, it is abut 350˜1,000 μm, within which the thickness of the light generating structure 202 is about 1 μm. As the present invention allows a much broader choice of materials having a wider range of refractive indices for the thick transparent layer 203, empirical study of numerous experiments of the present invention suggests that the thickness (T) of the thick transparent layer 203 should satisfy at least one of the following criteria so as to achieve an appropriate enhancement of light efficiency:
T≧0.005×A, or
T≧T′, or
T≧1 μm
where T′ is the thickness of the light generating structure. Based on actual measurement, it is found that, for instance, a thick transparent layer 203 made of GaP and having a thickness of 10 μm, the light efficiency of the LED structure is enhanced at least 20%.

Beneath the thick transparent layer 203, there is a metallic layer 205 functioning as a reflective mirror, and the light emitted from the light generating structure 202 is reflected and directed back through the thick transparent layer 203, which further increase the amount of light emitted from the sides of the LED structure. The metallic layer 205 is made of a pure metal or a metal nitride such as Au, Al, Ag, Titanium Nitride (TiNₓ), Zirconium Nitride (ZrNₓ). In contrast to the alloy reflective mirrors of prior arts, pure metal or metal nitride is used here to achieve much superior reflectivity. Please note that in alternative embodiments, there could be additional metallic layers between the metallic layer 205 and the underlying substrate 207. These additional metallic layers, made of a pure metal or an alloy metal, are for enhancing the boding to the substrate 207 in a wafer bonding process. An exemplary fabrication process of the present invention will be given later.

In order to achieve the required low resistance electrical conduction, a non-alloy ohmic contact layer 204 is interposed between the light generating structure 202 and the metallic layer 205. The non-alloy ohmic contact layer 204 is, but not limited to, an optically transparent or absorbing, p-type or n-type doped, semiconductor layer usually having a doping density at least 1E19/cm³. Typical examples of the non-alloy ohmic contact layer 204 includes, but is not limited to: carbon-doped AlAs, carbon-doped GaP, carbon-doped AlP, carbon-doped AlGaAs, carbon-doped InAlAs, carbon-doped InGaP, carbon-doped InAlP, carbon-doped AlGaP, carbon-doped GaAsP, carbon-doped AlAsP, carbon-doped AlGaInP, carbon-doped AlGaInAs, carbon-doped InGaAsP, carbon-doped AlGaAsP, carbon-doped AlInAsP, carbon-doped InGaAlAsP, Mg-doped AlAs, Mg-doped GaP, Mg-doped AlP, Mg-doped AlGaAs, Mg-doped InAlAs, Mg-doped InGaP, Mg-doped InAlP, Mg-doped AlGaP, Mg-doped GaAsP, Mg-doped AlAsP, Mg-doped AlGaInP, Mg-doped AlGalnAs, Mg-doped InGaAsP, Mg-doped AlGaAsP, Mg-doped AlInAsP, Mg-doped InGaAlAsP, Zn-doped AlAs, Zn-doped GaP, Zn-doped AlP, Zn-doped AlGaAs, Zn-doped InAlAs, Zn-doped InGaP, Zn-doped InAlP, Zn-doped AlGaP, Zn-doped GaAsP, Zn-doped AlAsP, Zn-doped AlGaInP, Zn-doped AlGalnAs, Zn-doped InGaAsP, Zn-doped AlGaAsP, Zn-doped AlInAsP, Zn-doped InGaAlAsP, carbon-doped InP, carbon-doped InAs, carbon-doped GaAs, carbon-doped InAsP, Mg-doped InP, Mg-doped InAs, Mg-doped GaAs, Mg-doped InAsP, carbon-doped InP, Zn-doped InAs, Zn-doped GaAs, and Zn-doped InAsP. Please note that some of the above doped compound semiconductors, depending on the constituent element composition, could be either optically transparent or optically absorbing.

In a second embodiment of the present invention, the non-alloy ohmic contact layer 204, after its deposition, is appropriately etched to form a number of recesses 2041, as illustrated in FIG. 2b, for controlling the injection current distribution. Another benefit of the recesses 2041 is that they reduce light absorption when the non-alloy ohmic contact layer 204 is made of an optically absorbing material. The depth of the etching is usually such that part of the immediately above layer (i.e., the thick transparent layer 203 in the present embodiment) is exposed.

In a third embodiment of the present invention, as depicted in FIG. 2c, a optically transparent and electrically conductive dielectric layer 2051 is interposed between the metallic layer 205 and the non-alloy ohmic contact layer 204, whose purpose is to prevent the intermixing between the metallic layer 205 and the non-alloy ohmic contact layer 204, and between the metallic layer 205 and the layer exposed by the recesses 2041 (i.e., the thick transparent layer 203 in the present embodiment), so as to maintain the reflectivity and the reflective surface flatness of the metallic layer 205. The dielectric layer 2051 is usually made of a transparent conductive oxide (TCO). Typical examples include, but are not limited to, Indium Tin Oxide (ITO), Indium Zinc Oxide (IZO), Tin Oxide (SnO), Antimony-doped SnO, Fluorine-doped SnO, Phosphorus-doped SnO, Zinc Oxide (ZnO), Aluminum-doped ZnO, Indium Oxide (InO), Cadmium Oxide (CdO), Cadmium Stannate (CTO), Copper Aluminum Oxide (CuAIO), Copper Calcium Oxide (CuCaO), and Strontium Copper Oxide (SrCuO).

A substrate 207 is beneath the metallic layer 205. Since the metallic layer 205 would reflect most (if not all) of the light incident toward the substrate 207, the optical characteristic of the substrate 207 is of no significance. The substrate 207 could be a semiconductor substrate, a metallic substrate, or other appropriate substrate. The substrate 207 could be electrically conductive or non-electrically conductive. Typical material choice for the electrically conductive substrate 207 includes, but is not limited to: doped Ge, doped Si, doped GaAs, doped GaP, doped InP, doped InAs, doped GaN, doped AlGaAs, doped SiC, doped GaAsP, Mo, Cu, and Al. Typical material choice for the non-electrically conductive substrate 207 includes, but is not limited to: Ge, Si, GaAs, GaP, InP, InAs, GaN, AlN, AlGaAs, SiC, GaAsP, sapphire, glass, quartz, and ceramic. Whether the substrate 207 is electrically conductive or not affects how the electrodes of the LED structure should be arranged in a subsequent chip process. If the substrate 207 is non-electrically conductive, the electrodes have to be arranged on the same side of the LED structure (i.e., a planar arrangement). If the substrate 207 is electrically conductive, the electrodes could be arranged either in a planar fashion or arranged on the top and bottom of the LED structure respectively (i.e., a vertical arrangement). These chip level details are omitted here for simplicity.

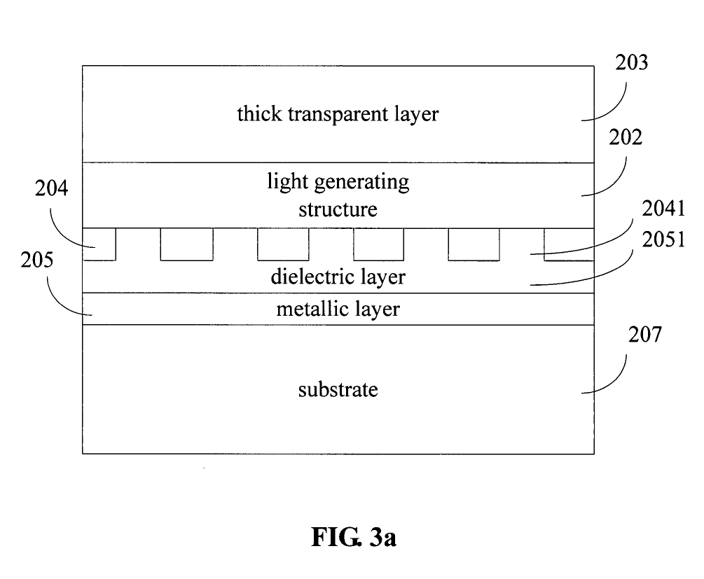

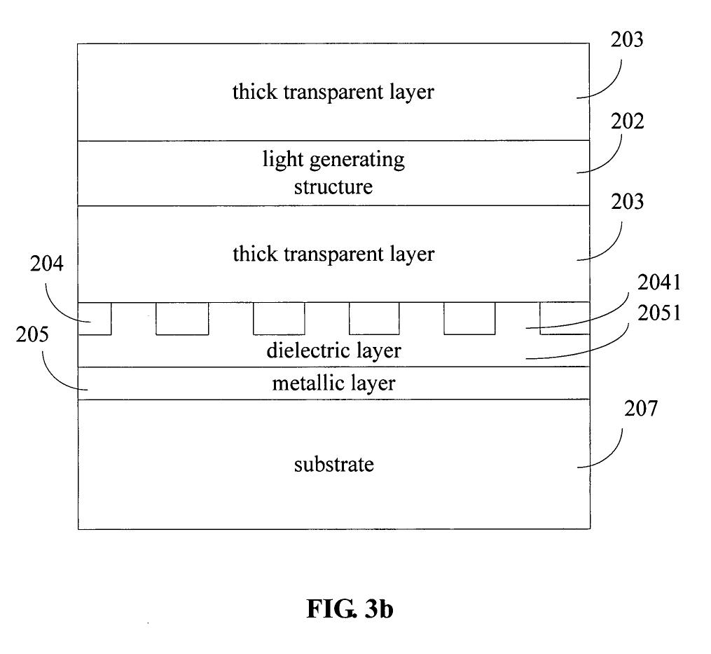

FIGS. 3a and 3b illustrate another two embodiments of the present invention. In comparison to the third embodiment shown in FIG. 2c, it could be readily seen that, in the fourth embodiment of FIG. 3a, the thick transparent layer 203 is positioned on top on of the light generating structure 202 while, in the fifth embodiment of FIG. 3b, there are two thick transparent layers 203 positioned both immediately on top of and beneath the light generating structure 202. Similarly, the embodiments shown in FIGS. 2a and 2b could have their thick transparent layers 203 positioned as shown in FIGS. 3a and 3b as well.

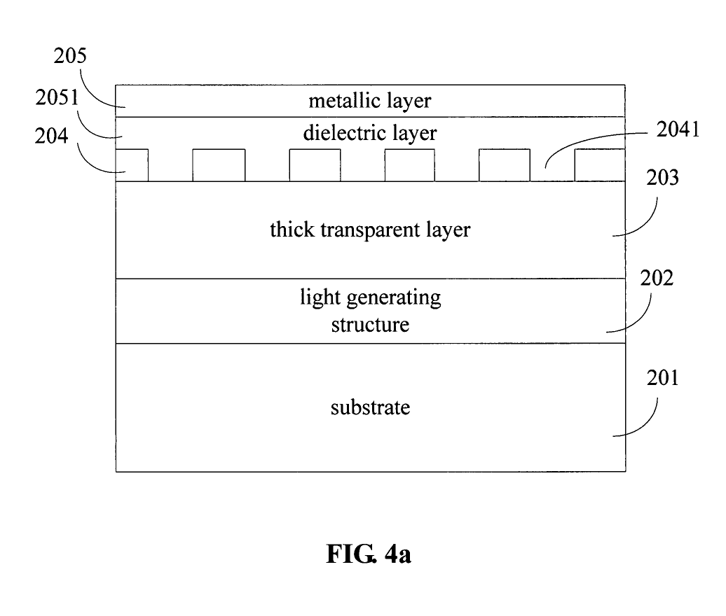

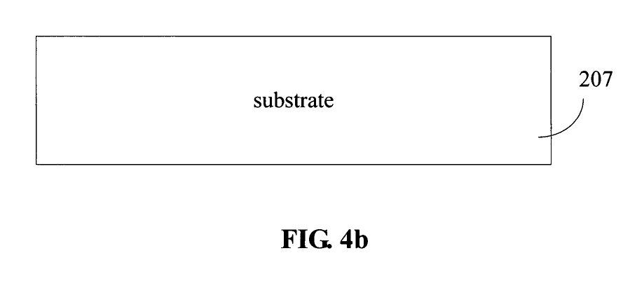

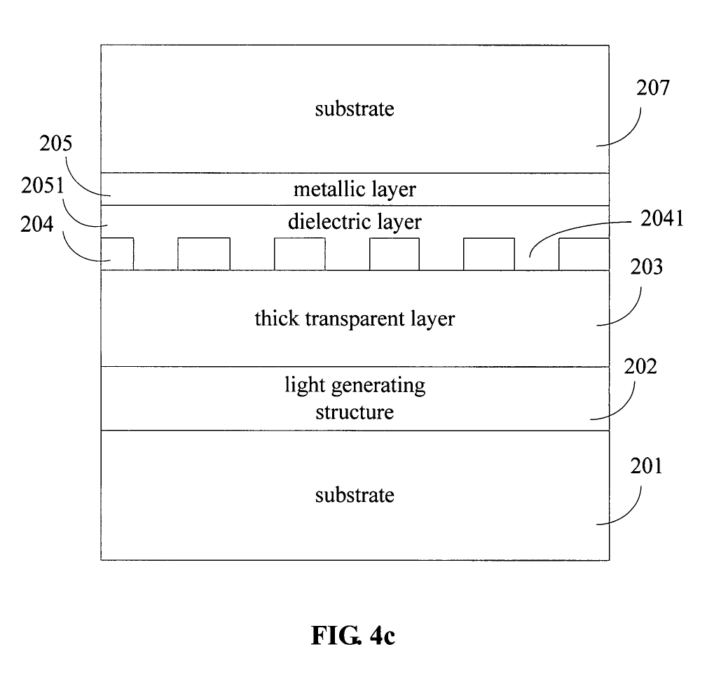

FIGS. 4a˜4c are schematic sectional views showing the process for forming the structure of FIG. 2c. As illustrated in FIG. 4a, a temporary growth substrate 201 is first provided and, then, a number of semiconductor layers forming the light generating structure 202 are sequentially grown on a side of the temporary growth substrate 201. The main consideration of substrate 201 is to achieve better luminous efficiency from the light generating structure 202. For example, substrate 201 is made of a material such as GaAs so that it is lattice-matched to the light generating structure 202.

Then, the thick transparent layer 202 and the non-alloy ohmic contact layer 204 is subsequently deposited on the light generating structure 202 using MOCVD (metallic organic chemical vapor deposition). The forming of these layers can be performed right after the formation of the light generating structure 202 in the same reactor. Or, in alternative embodiments, these layers could be re-grown on the light generating structure 202 after moving to separate reaction chambers. To improve the injection current distribution and/or reduce light absorption by the non-alloy ohmic contact layer 204, a number of recesses 2041 are configured by etching on the surface of the non-alloy ohmic contact layer 204. Then, the dielectric layer 2051 and the metallic layer 205 are sequentially coated on the non-alloy ohmic contact layer 204 using vacuum evaporation, deposition, sputtering, or plating techniques.

As illustrated in FIG. 4b, a permanent substrate 207 is prepared separately. Then a wafer bonding process is conducted to join the structure of FIG. 4a and the structure of FIG. 4b, with the metallic layer 205 interfacing with the permanent substrate 207, as shown in FIG. 4c. Compared to prior arts which wafer-bond the reflective mirror to the light generating structure, the present invention directly coats the metallic layer 205 (i.e., the reflective mirror) on the light generating structure 202 in vacuum prior to the wafer-bonding process. The mirror's reflective surface is not directly involved in the bonding interface during the wafer-bonding process. Therefore, roughness of the reflective surface or reactions and contaminations to the mirror's reflective surface can be avoided. The metallic layer 205 of the present invention thereby offers a much superior reflectivity than the reflective mirrors formed using prior arts.

The temporary growth substrate 201 is then removed. As the removal of the temporary growth substrate 201 is performed after the light generating structure 202 is bonded to the permanent substrate 207, the problem of light generating structure 202 being too thin to handle is avoided accordingly. Up to this point, a LED structure according to the present invention is formed. Subsequently, a conventional chip process could be conducted to package the LED structure into a chip.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A light emitting diode structure, comprising:
a substrate;
a metallic layer above said substrate;
a non-alloy ohmic contact layer above said metallic layer;
a light generating structure above said non-alloy ohmic contact layer; and
a thick transparent layer positioned at least in one of the following locations:
above said light generating structure, and between said light generating structure and said non-alloy ohmic contact layer.

2. The light emitting diode structure according to claim 1, wherein said metallic layer is made of one of a pure metal and a metal nitride.

3. The light emitting diode structure according to claim 2, wherein said metallic layer is made of one of the following materials: Au, Al, Ag, TiNₓ, and ZrN_{x.}

4. The light emitting diode structure according to claim 1, further comprising an optically transparent and electrically conductive dielectric layer positioned between said metallic layer and said non-alloy ohmic contact layer.

5. The light emitting diode structure according to claim 4, wherein said dielectric layer is made of a transparent conductive oxide.

6. The light emitting diode structure according to claim 5, wherein said dielectric layer is made of one of the following materials: ITO, IZO, SnO, Antimony-doped SnO, Fluorine-doped SnO, Phosphorus-doped SnO, ZnO, Aluminum-doped ZnO, InO, CdO, CTO, CuAlO, CuCaO, and SrCuO.

7. The light emitting diode structure according to claim 1, wherein the thickness of said thick transparent layer is at least 1 μm.

8. The light emitting diode structure according to claim 1, wherein said thick transparent layer is at least as thick as said light generating structure.

9. The light emitting diode structure according to claim 1, wherein said thick transparent layer is at least as thick as 0.005 times of the lateral dimension of said light generating structure.

10. The light emitting diode structure according to claim 1, wherein said thick transparent layer is made of one of a semiconductor material and a dielectric material, having a refractive index between 1.5 and 3.5 and a bandgap larger than the light energy emitted from said light generating structure.

11. The light emitting diode structure according to claim 10, wherein said thick transparent layer is made of one of the following materials: AlP, GaP, AlN, AlAs, AlGaP, GaAsP, AlGaAs, and Alₗ₋ₓGaₓIn_{y}P (x≦0.5, 0<y≦l).

12. The light emitting diode structure according to claim 1, wherein said non-alloy ohmic contact layer is a made of a doped semiconductor material.

13. The light emitting diode structure according to claim 12, wherein said non-alloy ohmic contact layer is made of one of the following materials: carbon-doped AlAs, carbon-doped GaP, carbon-doped AIP, carbon-doped AlGaAs, carbon-doped InAlAs, carbon-doped InGaP, carbon-doped InAIP, carbon-doped AlGaP, carbon-doped GaAsP, carbon-doped AlAsP, carbon-doped AlGaInP, carbon-doped AlGaInAs, carbon-doped InGaAsP, carbon-doped AlGaAsP, carbon-doped AlInAsP, carbon-doped InGaAlAsP, Mg-doped AlAs, Mg-doped GaP, Mg-doped AIP, Mg-doped AlGaAs, Mg-doped InAlAs, Mg-doped InGaP, Mg-doped InAIP, Mg-doped AlGaP, Mg-doped GaAsP, Mg-doped AlAsP, Mg-doped AlGaInP, Mg-doped AlGaInAs, Mg-doped InGaAsP, Mg-doped AlGaAsP, Mg-doped AlInAsP, Mg-doped InGaAlAsP, Zn-doped AlAs, Zn-doped GaP, Zn-doped AIP, Zn-doped AlGaAs, Zn-doped InAlAs, Zn-doped InGaP, Zn-doped InAIP, Zn-doped AlGaP, Zn-doped GaAsP, Zn-doped AlAsP, Zn-doped AlGaInP, Zn-doped AlGaInAs, Zn-doped InGaAsP, Zn-doped AlGaAsP, Zn-doped AlInAsP, Zn-doped InGaAlAsP, carbon-doped InP, carbon-doped InAs, carbon-doped GaAs, carbon-doped InAsP, Mg-doped InP, Mg-doped InAs, Mg-doped GaAs, Mg-doped InAsP, carbon-doped InP, Zn-doped InAs, Zn-doped GaAs, and Zn-doped InAsP.

14. The light emitting diode structure according to claim 1, wherein said non-alloy ohmic contact layer has a plurality of recesses along the surface facing said metallic layer.
